(19) United States
(12) Patent Application Publication
(10) Pub. No.: US 2022/0373598 A1
(43) Pub. Date: Nov. 24, 2022

(54) SHORT PATTERN WAVEFORM DATABASE BASED MACHINE LEARNING FOR MEASUREMENT

(71) Applicant: Tektronix, Inc., Beaverton, OR (US)

(72) Inventors: Kan Tan, Portland, OR (US); John J. Pickerd, Hillsboro, OR (US)

(73) Assignee: Tektronix, Inc., Beaverton, OR (US)

(21) Appl. No.: 17/747,954

(22) Filed: May 18, 2022

Related U.S. Application Data
(60) Provisional application No. 63/191,908, filed on May 21, 2021.

(51) Int. Cl. G01R 31/3183; G01R 31/319; G01R 31/28

(52) U.S. Cl. CPC G01R 31/318371; G01R 31/31924; G01R 31/31919; G01R 31/2834; G01R 31/2841

(57) ABSTRACT

A test and measurement system includes a test and measurement device configured to receive a signal from a device under test, and one or more processors configured to execute code that causes the one or more processors to generate a waveform from the signal, apply an equalizer to the waveform, receive an input identifying one or more measurements to be made on the waveform, select a number of unit intervals (UIs) for a known data pattern, scan the waveform for the known data patterns having a length of the number of UIs, identify the known data patterns as short pattern waveforms, apply a machine learning system to the short pattern waveforms to obtain a value for the one or more measurements, and provide the values of the one or more measurements for the waveform. A method includes receiving a signal from a device under test, generating a waveform from the signal, applying an equalizer to the waveform, receiving an input identifying one or more measurements to be made on the waveform, selecting a number of unit intervals (UIs), scanning the waveform to identify short pattern waveforms having a length equal to the number of UIs, applying a machine learning system to the short pattern waveforms to obtain a value for the one or more measurements, and providing the values of the one or more measurements for the waveform from the machine learning system.

### CROSS-REFERENCE TO RELATED APPLICATIONS

This disclosure claims benefit of U.S. Provisional Application No. 63/191,908, titled “SHORT PATTERN WAVEFORM DATABASE BASED MACHINE LEARNING FOR MEASUREMENT,” filed on May 21, 2021, the disclosure of which is incorporated herein by reference in its entirety.

### TECHNICAL FIELD

This disclosure relates to test and measurement systems and methods, and more particularly to applying machine learning to measurements of a signal from a device under test.

### BACKGROUND

Many electronic devices and systems employ high-speed signals for communication and data transfer, in particular signals sent between transmitters and receivers according to high speed serial data protocols such as Peripheral Component Interconnect Express (PCIE) and Ethernet, for example. Traditionally, test and measurement instruments, such as oscilloscopes, have been used to acquire these high speed signals and generate eye diagrams to measure the characteristics of the signals.

When the signal speed increases, equalizers in the transmitter and receiver are widely used to improve the system performance. For example, a PCIE Generation 5 (PCIE Gen5) receiver has a 3-tap decision feedback equalizer (DFE) in addition to a continuous time linear equalizer (CTLE). See, e.g., PCI-SIG, “PCI Express Base Specification 5.0, Version 10,” 2019, available at https://pcisig.com/specifications/. The IEEE 100G/400G Ethernet standards define measurements with a 5-tap feed forward equalizer (FFE). See for example, “IEEE P802.3bs-2017,” 2017, available at http://standards.ieee.org/findstds/standard/802.3bs-2017.html; “IEEE P802.3cd-2018,” 2018, available at http://standards.ieee.org/develop/project/802.3cd.html.

When the receivers have equalizers, some of the measurements are performed on the equalized signals. For example, in PCIE Gen5, the eye height and eye width measurements are defined based on the eye diagram of the equalized waveform.

In some approaches, a machine learning system may use the eye diagrams prior to equalization as inputs. The machine learning system can then provide a desired measurement. However, the eye diagrams prior to equalization do not include time sequence information, and the post-equalizer waveforms may differ enough from the pre-equalizer waveforms, making the process inaccurate.

### BRIEF DESCRIPTION OF THE DRAWINGS

FIG. 1 shows an embodiment of an optical transceiver test system.

FIG. 2 shows an illustration of the TDECQ measurement.

FIG. 3 shows two examples of eye diagrams before and after application of an equalizer.

FIG. 4 shows a graphical representation of the taps of a 5-tap feed forward equalizer.

FIG. 5 shows a partial display of a pattern waveform having time sequence information.

FIG. 6 shows examples of waveform databases with different pattern lengths.

FIG. 7 shows examples of waveform databases for different symbol sequences.

FIG. 8 shows an embodiment of a test and measurement device.

FIG. 9 shows an embodiment of a machine learning system including a short pattern waveform database.

FIG. 10 shows an example of a short pattern waveform tensor image.

FIG. 11 shows an example of a short pattern waveform tensor image.

FIG. 12 shows examples of short pattern waveform databases for the patterns with length of 1 symbol.

### DESCRIPTION

The embodiments involve systems and methods that apply machine learning techniques for performing signal measurements on incoming waveforms. The embodiments generally employ a database of short patterns developed from waveforms. This allows for faster analysis using machine learning than if the process used full or partial pattern waveforms. Instead, the embodiments use a machine learning system trained on short patterns of different numbers of symbols stored in one or more databases. The system can then scan for these patterns and produce the measurements associated with the short patterns. The embodiments improve accuracy of the measurement compared to techniques using eye diagrams.

In addition, as mentioned above, as signal speeds increase many systems employ equalizers to improve the system performance. As mentioned above Peripheral Component Interface Express (PCIE) Gen6 uses a 3-tap decision feedback equalizer (DFE) in addition to a continuous time linear equalizer (CTLE). In another example, the Institute for Electrical and Electronic Engineers (IEEE) standard 802.3 for 100G/400G specify the transmitter and dispersion eye closure quaternary (TDECQ) measurement as key pass/fail criteria for 26GBaud and 53GBaud PAM4 optical signaling. This provides an example to demonstrate the issues with using waveforms without time sequence information as inputs to a machine learning system.

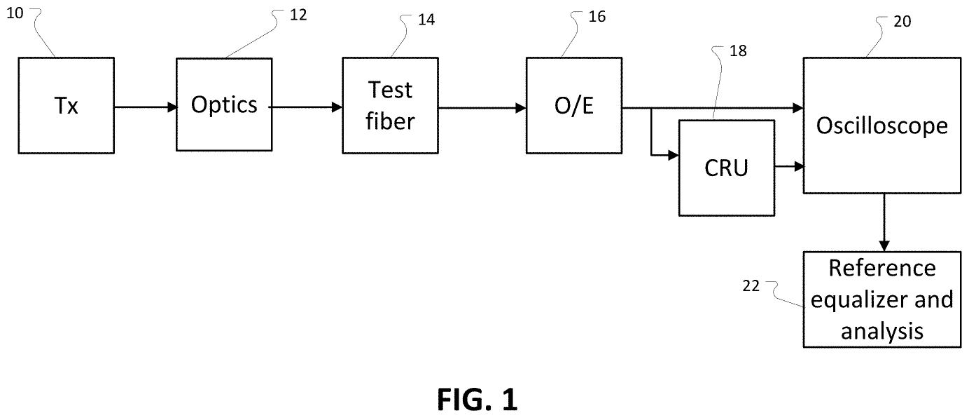

The TDECQ measurement involves a 5-tap FFE. FIG. 1 illustrates a test block diagram showing acquisition of an optical signal from a transmitter (Tx) or transceiver under test 10. The optical signal may interact with optics 12, such as polarization rotators, and/or variable reflectors. The signal goes through a test fiber 14 and reaches an optical to electrical (O/E) converter, which converts the optical signal to the electrical signal. An oscilloscope 20, which may include a clock recovery unit (CRU) 18 then samples the resulting electrical signal and digitizes the signal. The digitized samples are saved as a waveform.

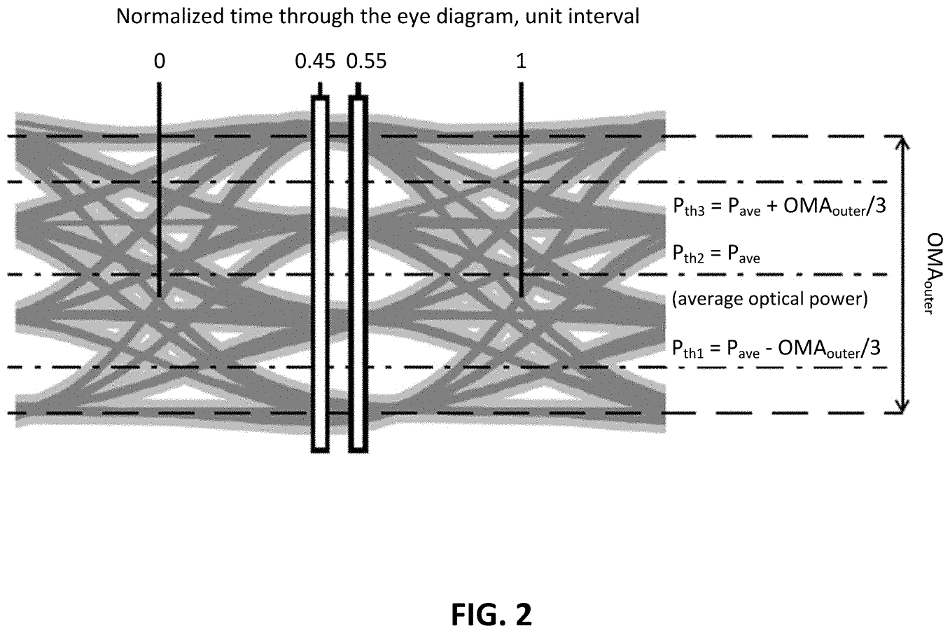

A reference equalizer and analysis module 22 in conventional oscilloscopes may then perform the TDECQ measurement and analysis. FIG. 2 shows an example of a diagram used in performing the TDECQ measurement. In this example, the waveform results from a 5-tap feed forward equalizer (FFE) with 1 unit interval (UI) spacing optimized to minimize the TDECQ value. The “0” and “1” interval marks the UI spacing.

The TDECQ value is computed with the following formula (Eq 1):

$$TDECQ = 10 {log}_{10} ( \frac{{OMA}_{o u t e r}}{6 \times {Q}_{r} \times \sqrt{{σ}_{G}^{2} + {σ}_{S}^{2}}} ) \qquad Eq 1$$

Where OMAₒᵤₜₑᵣ relates to the power of the optical signal. Qᵣ is a constant value related to the symbol error ratio. σ_{G}² is the standard deviation of a weighted Gaussian noise that can be added to the eye diagram shown in FIG. 2 and still get the larger of symbol error ratio at the two vertical slicers, at 0.45 and 0.55, 0.1 UI apart is 4.8 e-4. The term σ_{S} represents the scope noise recorded when no signal is fed into the O/E module.

A single TDECQ measurement on the compliance pattern SSPRQ (short stress pattern random quaternary) takes seconds to complete using conventional methods. International Pat. App. No. PCT/US2020/059086, filed May 11, 2020, entitled “DEVICES, SYSTEMS, AND METHODS FOR PROCESSING OPTICAL COMPONENTS,” discloses a machine learning technique intended to reduce time to acquire measurements for optical transceivers, including TDECQ. One of the disclosed machine learning approaches takes an eye diagram image representation of the waveform as the input to a neural network for training and then for testing optical transceivers.

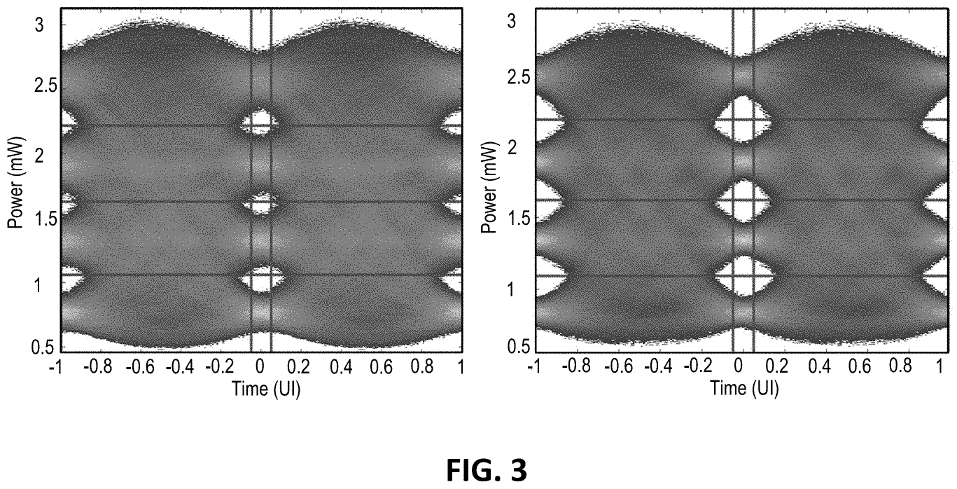

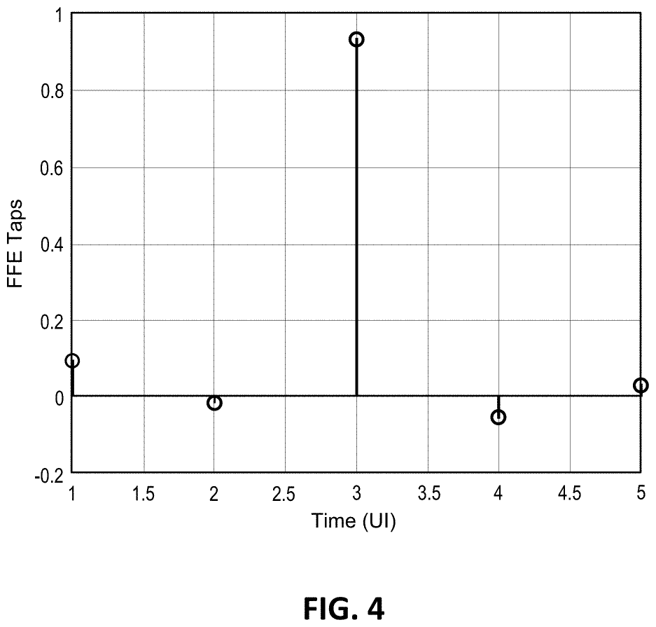

FIG. 3 shows examples of an eye diagram before, on the left, and after, on the right, the application of the FFE to the waveform. The eye diagram on the right, after application of the FFE, has a larger eye opening. Using the eye diagram before FFE as the input to the neural network for machine learning does not provide the information of the eye diagram after FFE. The 5 FFE taps are applied to the samples in the 5 UIs (unit intervals) around the current sample. The eye diagram before FFE does not contain the information of time sequence since all the samples are wrapped to 1 or 2 UIs. FIG. 4 shows the FFE taps used in this example to create the eye diagram on the right side of FIG. 3.

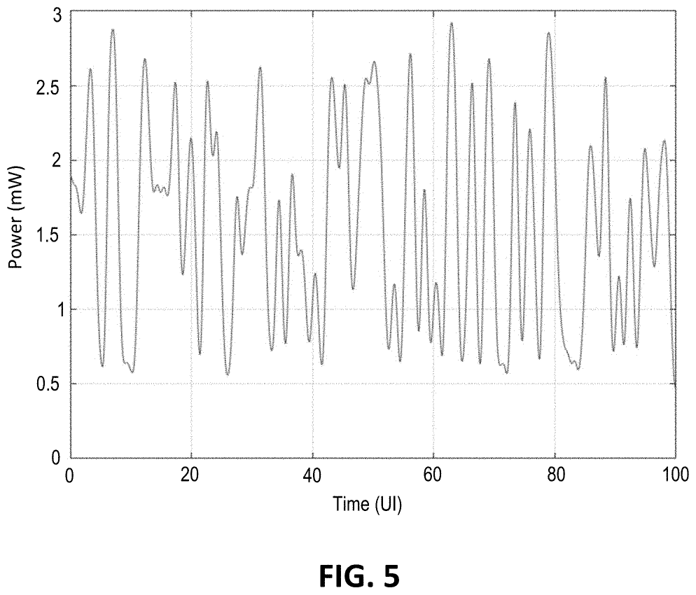

In contrast, as shown in FIG. 5, in the actual pattern waveform, every sample has a time associated with it. The time sequence information is ready to be used by the FFE operation. An alternative machine learning approach to using eye diagrams uses the equalized actual pattern waveform as the input to a neural network for training and then for testing.

However, the pattern waveform may have too many samples making it impractical for training. For example, the SSPRQ pattern has 65535 symbols. With multiple samples per UI, this results in a very large sampled waveform. Using the actual sampled waveform would take more time to perform machine learning training. One option would use a partial pattern waveform, but this approach may miss essential information in the waveform that could result in increasing measurement error.

As discussed above, the embodiments here employ a short pattern waveform database with a machine learning module, for example a neural network, to perform signal measurements. Additionally, for the measurements that require equalizers, to get more accurate results, the input data to the neural network should contain time sequence information, since the equalizers operate on the time-sequenced samples. A conventional eye diagram has lost the time sequence information between symbols. The embodiments here use short pattern waveforms that contain time sequence information, providing a solution to waveform size and accuracy, and time sequence issues.

The process constructs short pattern waveform databases based on short patterns found in the waveform. The term “short” as used here means portions of the waveforms that have a length equal to a predetermined number of UIs. The system scans through the data pattern, identifies and extracts a short pattern waveform, and puts the waveform samples for the extracted short pattern waveform into the corresponding short pattern waveform database. This scanning process can repeat, or operate in parallel, to build multiple short pattern waveform databases for each short pattern waveform of interest. The database selected may depend upon the type of signaling, such as pulse amplitude modulated 4-level (PAM4) signaling or non-return-to-zero (NRZ) signaling and the signal level of the pattern. For example, PAM4 has 4 levels, corresponding to symbols 0, 1, 2, and 3, and NRZ has two levels, either symbols 1 or 0. In the below discussion, the variable S indicates the number of signal levels from the type of signaling. The data pattern is often known or can be detected.

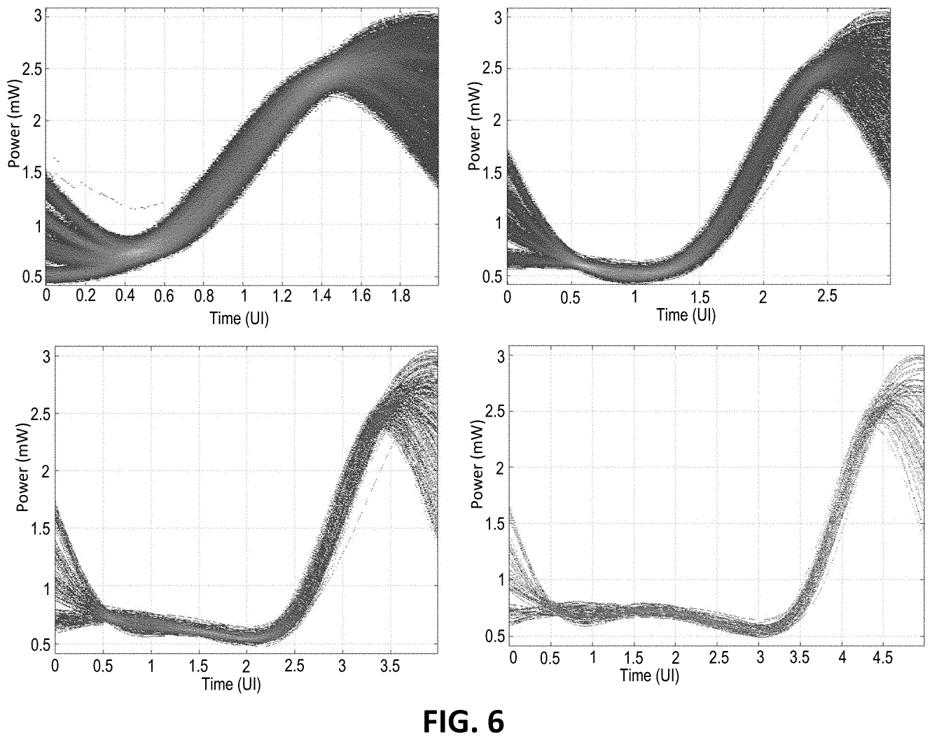

A number of UIs, N, defines the length of the short pattern. Selection of the length may take into account the impact of the previous symbol on the current symbol. FIG. 6 shows the waveform databases with different number of previous symbols leading to the current symbol of 3 for a PAM4 signal. For example, consider 1 to 4 zeros as previous symbols to the symbol 3, which represents a signaling level in PAM4 signals. With more symbols to consider, the waveform database for a current symbol is cleaner, meaning there is less mixed impact from previous symbols. As used here, the term “waveform database” means a collection of all portions of the overall pattern waveform that have the same symbol pattern over the given short pattern length, N. As will be discussed in more detail below, the system may use subsets of the databases, where the subset used depends upon the pattern of interest and/or the measurement to be made on the acquired waveform.

In the top left, the waveform database comprises all of the short pattern waveforms shown, each across 2 UIs, and each having a pattern length of 2, with the short pattern being 03. The top right shows the waveform database for short pattern waveforms with two 0 symbols before the 3 symbol, with the short pattern being 003, across 3 UIs. The lower left shows the waveform database for 4 symbols, with the short pattern being 0003, and the lower right for 5 symbols, with the short pattern being 00003.

The design of the receiver equalizer compensates for the channel impairment such as channel loss. The channel loss is reflected in the inter-symbol-interference. For measurements that require an equalizer, one can select the length of the short pattern to match the reach of the equalizer. This provides the essential information about time sequence so that the data fed into the machine learning block yields the accurate model and provides accurate measurement results.

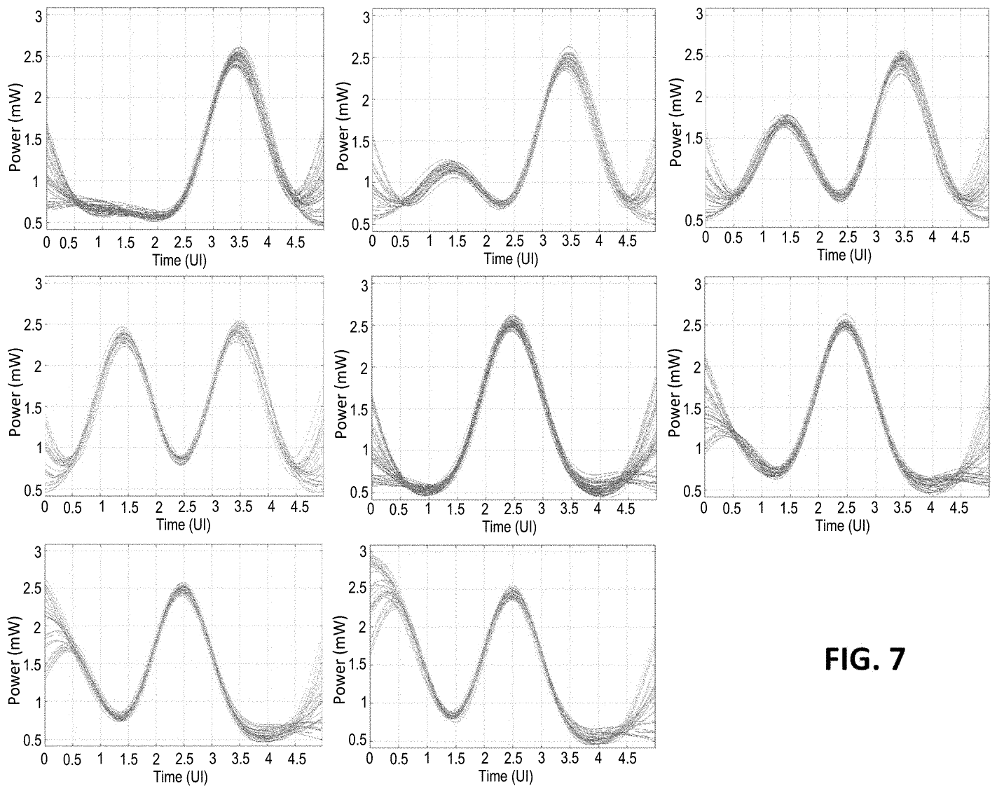

For example, the TDECQ measurement requires 5-tap FFE, so the process sets the short pattern length to 5. As shown in FIG. 7, the short pattern waveform databases created from the SSPRQ data pattern carries the time sequence information for each short pattern, enabling the machine learning system to capture the essential information of the data to get the accurate measurement results. The top row of the images shows the short pattern waveform databases for symbol sequences 00030, 01030, and 02030 from left to right. The middle set shows short pattern databases for symbol sequences 03030, 00300, and 10300 from left to right. The bottom row shows symbol sequences 20300 and 30300.

In order to employ these databases, the machine learning system must first receive the waveforms as an input in a format that allows for fast and accurate training and run times. Referring back to FIG. 1, the test and measurement device such as an oscilloscope 20, receives the signals from the transceivers, and produces the waveforms. One should note that while the devices under test (DUTs) in this discussion comprise optical transceivers, the system and methods used here apply to any type of DUT, optical or electrical.

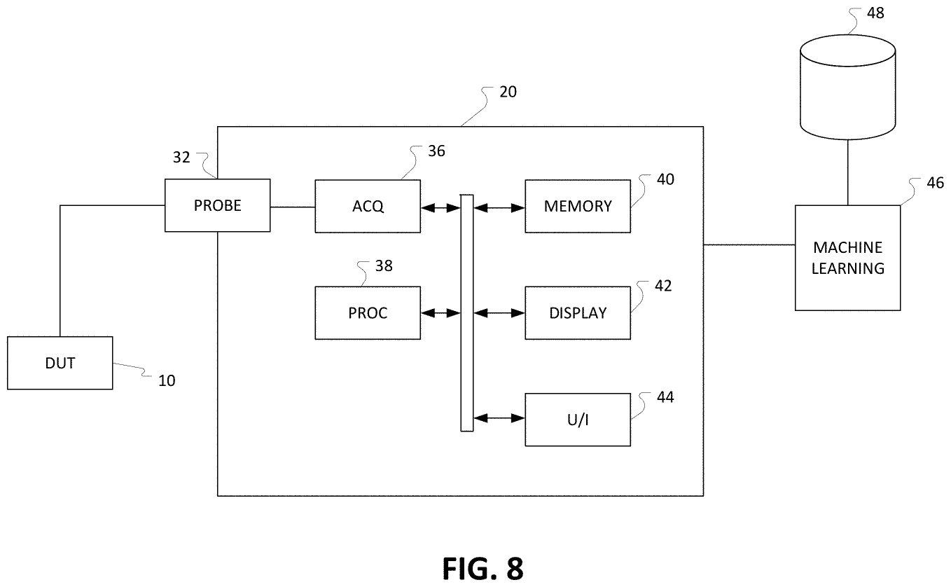

FIG. 8 shows an embodiment of a test and measurement device 20 usable with a machine learning system 46 to provide performance measurements for DUTs such as 34. The test and measurement device generally interfaces with the DUT 34 through a probe 32. As discussed in regards to FIG. 1, the input path may include an optical-to-electrical converter to convert an incoming optical signal to an electrical signal. The acquisition circuitry 36 of the device 20 may include analog-to-digital converters (ADCs) that digitize the incoming signal and clock recovery and triggering hardware that provides the timing. A processor 38 may control the acquisition hardware and the rendering of the signal into a waveform. The display 42 displays the resulting waveform for a user. User interface devices 44, which may include any touch screen capability on the display, allow the user to interact with the device to select from pre-set menus. The selections may include types of measurements desired for the waveforms, the length of the short pattern waveforms, etc. The length may result from pre-selected or pre-set variables in the system, etc.

The memory 40 may allow the processor to store and work with the waveform data and may store executable code. The overall system including the test and measurement device will have one or more processors configured to execute code that will cause the one or more processors to execute various tasks described here. The one or more processors may include one or more processors on the test and measurement device and one or more processors in the machine learning system 46. The machine learning system may comprise a separate computer device or devices that receives data from the test and measurement device. A separate database structure 48 may store all of the waveform databases, or they may comprise a part of the machine learning system and its computing device(s).

Upon reception of the signal from the DUT, the test and measurement instrument will generate a waveform of the signal and apply one or more equalizers to the waveform. This means that the equalizer will act on the samples that make up the waveform. One or more processors in the system may accomplish these tasks. The system receives an input that designates a length, N, of the short pattern in terms of a number of UIs. As discussed above, the user may provide this input, or the system may determine it from pre-defined parameters, etc. Similarly, one or more desired performance measurement(s), such as TDECQ or other measurement would be identified. In some embodiments, the short pattern length may be automatically determined based on the selected measurement. For example, if TDECQ measurement is selected, the system may automatically determine the short pattern length to be 5 UIs, corresponding to the reach of the 5-tap FFE equalizer specified for the TDECQ measurement.

The system then scans the waveform for known patterns of that length to produce a set of short pattern waveforms. In one embodiment, the system may convert the short pattern waveforms into tensors, but for purposes of discussion here, these are still considered short pattern waveforms. Once the short patterns are identified, they are submitted to the machine learning system. The machine learning system then returns values of the desired measurement(s). The system operates much more quickly and provides the values for the measurements much faster than calculating the measurements in the conventional manner.

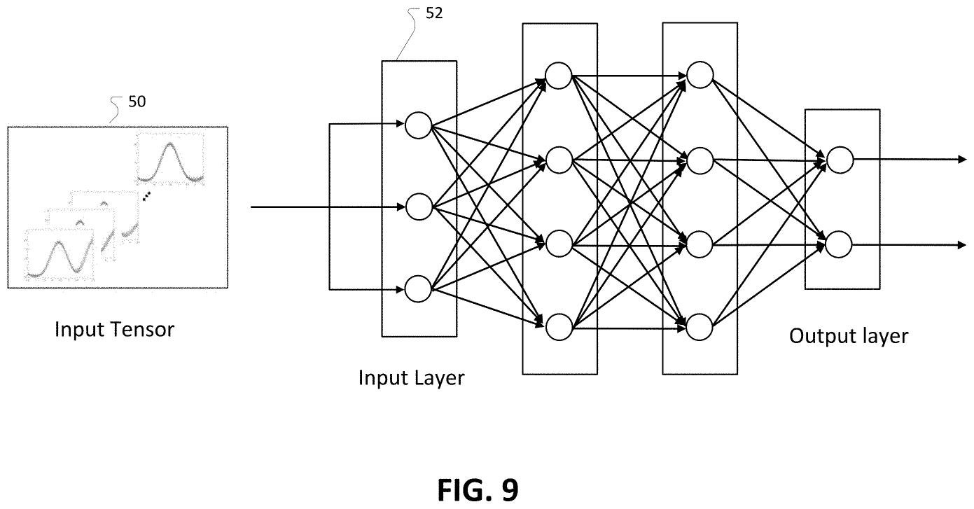

FIG. 9 shows an embodiment of a machine learning structure using the short pattern waveform database. The short pattern waveform databases may take the form of a machine-learning-friendly format such as tensors 50 as input to the neural network for training and for testing. The outputs are the measurement results. The measurement result could be a scalar value or a vector, and can be used as a label for machine learning. During training, both the short pattern waveforms and the measurement results are used. During testing, only the short pattern waveform are used to get the measurement result.

The training process involves a process to pick the length of the short pattern. It can start with a small value, such as 3. The number of possible short symbol sequences L is determined by the signal levels S and short pattern length N in equation (2).

L=S^{N} (2)

For example, for PAM4 signaling, there may be 4³=64 waveform databases for a 3-symbol short pattern. For NRZ signaling, there may be 2³=8 waveform databases for a 3-symbol short pattern. As mentioned above, this can lead to extremely large databases that cover all of the short patterns in a particular database. For example, in PAM4 signaling, if N=5, there are 4⁵ or 1024 possible short patterns. Training the machine learning system would require many examples of each of the 1024 possible short patterns with each patterns associated measurements. This would take too much time and too many resources to train the machine learning system.

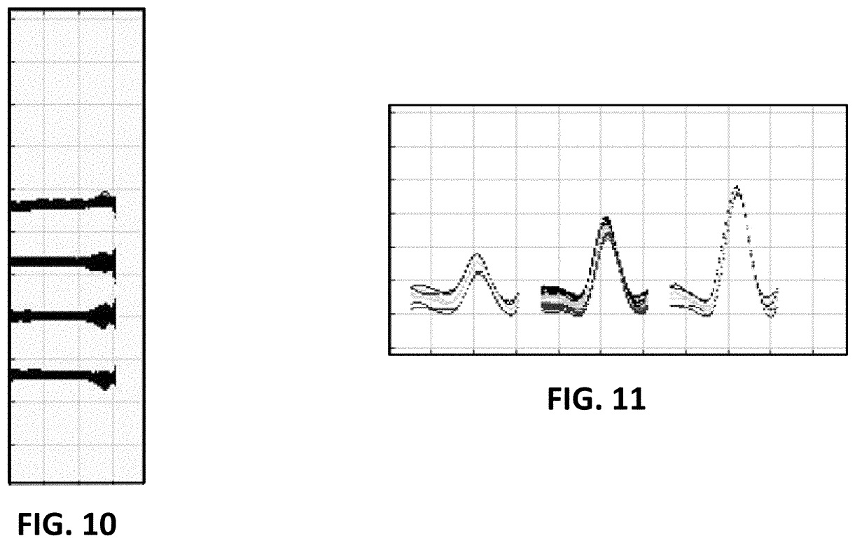

In one embodiment, the system uses a subset of the possible short patterns from the database and the associated measurements for the short patterns. For example, assume the desired result has the machine learning system in the form of a deep learning network to predict tuning parameters that affect the four levels of the PAM4 signal. The system would use four short patterns that have consecutive UIs with the same level. In one embodiment, all four of these sequences are placed into one tensor image that becomes the input to the deep learning system for both runtime and training. FIG. 10 shows an example of a tensor image of four sequences for the four levels.

For example, one tuning parameter in the system could adjust the signal gain, causing all four levels to become closer together for lower gain settings and farther apart for high gain settings. An offset control in the transmitter would cause all four symbols to move or down vertically in the image but the distances between them would remain the same. A third transmitter parameter might cause both gain and offset to change. By using this image, which represents a subset of the short pattern databases that include all of the possible short pattern waveforms, it allows the deep learning network to easily see the effects of all three parameters and make predictions about their values.

In another example, the machine learning system could predict FFE taps. Using short pattern waveforms that show pulses as shown in FIG. 11 work better for the machine learning because the FFE taps affect the pulse shapes in ways that allow the deep learning network to associate the pulse shape with a set of several FFE taps. The image of FIG. 11 shows a single tensor image that contains three short patterns laid out end to end horizontally. Each sequence shows a different pulse height from level 0 of the PAM4 signal to level 1 for the first pulse, level 0 to level 2 for the second pulse, and level 0 to level 3 for the third pulse. The deep learning network can look at this image and predict what the multiple FFE tap values are. Other applications of course exist, these just provide examples of how the machine learning system can use the images.

If the machine learning training does not yield the desired result from the current short pattern length setting, the process may increase the short pattern length, and try training again. The process may also select a different subset of short training patterns to use for training. Since the short pattern length would alter the pattern used, this also comprises selecting a different subset of short training patterns. The short pattern waveforms used for training may be referred to as short training pattern waveforms, or short training patterns.

As mentioned above, the short pattern length is based upon, but should not exceed, the reach of the equalizer by “too much.” For example, if the equalizer is a 5-tap FFE, then the pattern length should not exceed 5 by too many UIs. For example, the pattern length can be chosen to be 5, 6, or 7. If the equalizer is a 3-tap DFE, then the pattern length should not exceed 4 by too much since the DFE only looks at previous 3 symbols. The determination of what “too much” means may depend upon the nature of the input to the machine learning system. For example, in one embodiment, where the input of the neural network is image data as discussed above, the image size limitation may drive the number of UIs, or length, of the pattern. In one embodiment, the image size is limited to 224×224 pixels in order to employ a machine learning system designed to accept input images of that size.

Once the process finds the proper short pattern length that yields the desired machine learning results, the process can check the weights, or coefficients, in the input layer 52. This allows identification of the connections that have low weights associated with them, which may involve comparison against a threshold. The system may remove the corresponding short pattern waveform databases from the input to reduce the input data size and see if the training results still meet the requirements. Some machine learning tools have the feature of dimension reduction to reduce the input data size automatically. One may view this process as dimensionality reduction.

The discussion up to this point has mostly focused on PAM-4 signaling and associated waveform databases. When one sets N to different values, the short pattern waveform database approach can also cover other approaches for machine learning such as the conventional eye diagram approach, and the full data pattern waveform approach.

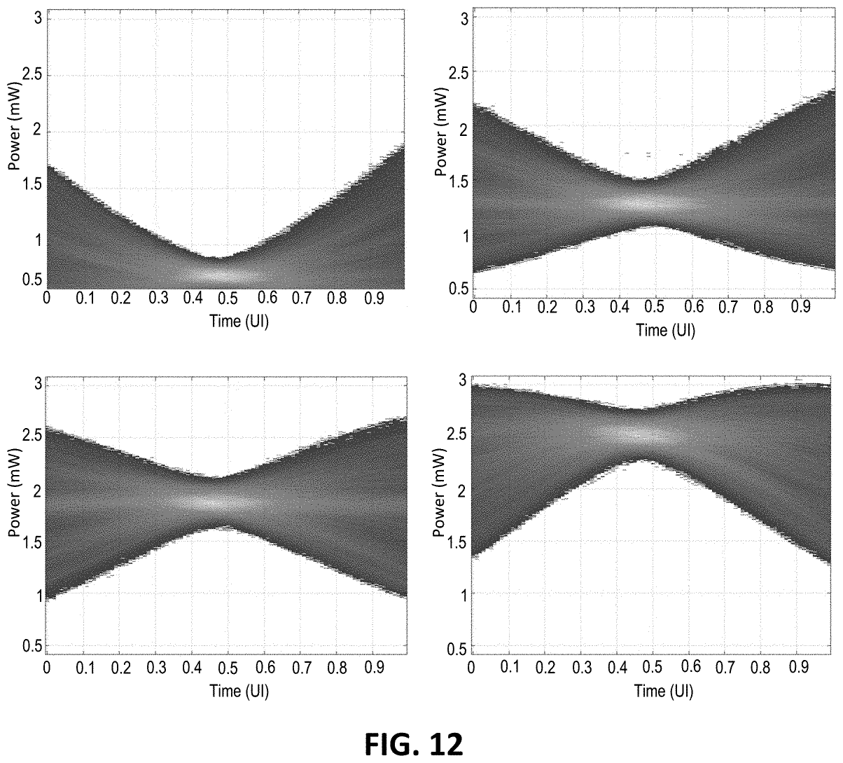

When N is set to 1, there are 4 short pattern waveform databases for PAM4 signals as shown in FIG. 12, with 0 in the upper left, 1 in the upper right, 2 in the lower left, and 3 in the lower right. Superposition of the 4 waveform databases will yield a conventional eye diagram. It can be expected that when the length N is set to 1, the short pattern waveform database approach for machine learning will yield similar result as when machine learning uses conventional eye diagrams.

When N is set to the length of the full pattern waveform, there is only one short pattern waveform database that has data in it. This short pattern waveform database has the same symbol sequence as the signal's full pattern. The short pattern waveform database approach allows flexible setting of N, this enables adjustment between accuracy and speed of measurement using machine learning.

This approach can also improve other measurements that requires limited time sequence information such as, for example, inter-symbol-interference jitter measurement, among others.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

### Examples

Illustrative examples of the disclosed technologies are provided below. An embodiment of the technologies may include one or more, and any combination of, the examples described below.

Example 1 is a method, comprising: receiving a signal from a device under test; generating a waveform from the signal; applying an equalizer to the waveform; receiving an input identifying one or more measurements to be made on the waveform; selecting a number of unit intervals (UIs); scanning the waveform to identify short pattern waveforms having a length equal to the number of UIs; applying a machine learning system to the short pattern waveforms to obtain a value for the one or more measurements; and providing the values of the one or more measurements for the waveform from the machine learning system.

Example 2 is the method of Example 1, wherein the applying the machine learning system to the short pattern waveforms comprises applying the machine learning system to tensors as the short pattern waveforms.

Example 3 is the method of either of Examples 1 or 2, wherein applying the machine learning system comprises using one or more short pattern databases to analyze the short pattern waveform.

Example 4 is the method of Example 3, wherein using one or more short pattern databases comprises using only a subset of the one or more short pattern databases.

Example 5 is the method of Example 3, wherein using one or more short pattern databases further comprises removing short pattern databases from the machine learning system that have coefficient values below a threshold to reduce input data size.

Example 6 is the method of any of Examples 1 through 5, wherein selecting the number of UIs comprises selecting the number of UIs based upon a number of taps of the equalizer.

Example 7 is the method of any of Examples 1 through 6, wherein selecting the number of UIs comprises selecting the number of UIs based on the one or more measurements to be made on the waveform.

Example 8 is the method of any of Examples 1 through 7, further comprising training the machine learning system, the training comprising: setting a length of a short pattern to be used; selecting a set of short training patterns from a waveform and associated measurements for the set of short training patterns for use by the machine learning system as datasets; testing the machine learning system to determine if results produced by the machine learning system meet a desired result; and selecting a different set of the short training patterns and repeating the testing using the different set of short training patterns when the results do not meet the desired result.

Example 9 is the method of Example 8, wherein selecting the different set of the short training patterns comprises selecting a different set of short training patterns of a same length, or selecting a different set of short training patterns having a longer length.

Example 10 is the method of Example 9, wherein the short patterns are stored in a number of short pattern databases, wherein the number, L, of short pattern sequence databases depends upon a number of signal levels, S, used in a type of signaling, and a pattern length, N, according to the relationship L=S^{N}.

Example 11 is a test and measurement system, comprising: a test and measurement device configured to receive a signal from a device under test; and one or more processors configured to execute code that causes the one or more processors to: generate a waveform from the signal; apply an equalizer to the waveform; receive an input identifying one or more measurements to be made on the waveform; select a number of unit intervals (UIs) for a known data pattern; scan the waveform for the known data patterns having a length of the number of UIs; identify the known data patterns as short pattern waveforms; apply a machine learning system to the short pattern waveforms to obtain a value for the one or more measurements; and provide the values of the one or more measurements for the waveform.

Example 12 is the test and measurement system of Example 11, wherein the short pattern waveforms comprise tensors.

Example 13 is the test and measurement system of either Examples 11 or 12, wherein the code that causes the one or more processors to apply the machine learning system to the short pattern waveforms comprises code that causes the one or more processors to use one or more short pattern waveform databases.

Example 14 is the test and measurement system of Example 13, wherein the code that causes the one or more processors to use one or more short pattern waveform data bases further comprises code that causes the one or more processors to remove short pattern waveform databases from the machine learning system that have coefficient values below a threshold to reduce input data size.

Example 15 is the test and measurement system of Example 13, wherein the code that causes the one or more processors to use one or more short pattern waveform databases further comprises code that causes the one or more processors to use only a subset of the one or more short pattern waveform databases.

Example 16 is the test and measurement system of any of Examples 11 through 15, wherein the code to cause the one or more processors to select a number of UIs comprises code to select a number of UIs based upon a number of taps of the equalizer to be applied to the waveform.

Example 17 is the test and measurement system of any of Examples 11 through 16, wherein the code that causes the one or more processors to scanning the waveform to identify the known data patterns as short pattern waveforms comprises code to select short pattern waveforms and include time sequence information.

Example 18 is the test and measurement system of any of Examples 11 through 17, wherein the one or more processors are further configured to execute code to train the machine learning system, comprising: set a length of a short training pattern to be used and a subset of the short training patterns with the set short pattern length; select a subset of available short training patterns from a waveform and associated measurements for the short training patterns to be provided a machine learning system as datasets; test the machine learning system to determine if results produced by the machine learning system meet a desired result; and select a different subset of the short training patterns, and repeat the testing when the results do not meet a desired result.

Example 19 is the test and measurement system of Example 18, wherein the code that causes the one or more processors to select a different subset of the short training patterns comprises selecting one of a different subset of the short training patterns with a same length and a different subset of the short training patterns of a longer length.

Example 20 is the test and measurement system of any of Examples 11 through 19, wherein the short patterns are stored in a number of short pattern databases, wherein the number, L, of short pattern sequence databases depends upon a number of signal levels, S, used in a type of signaling, and a pattern length, N, according to the relationship L=S^{N}.

Although specific aspects of the disclosure have been illustrated and described for purposes of illustration, it will be understood that various modifications may be made without departing from the spirit and scope of the disclosure. Accordingly, the disclosure should not be limited except as by the appended claims.

We claim:

1. A method, comprising:
receiving a signal from a device under test;
generating a waveform from the signal;
applying an equalizer to the waveform;
receiving an input identifying one or more measurements to be made on the waveform;
selecting a number of unit intervals (UIs);
scanning the waveform to identify short pattern waveforms having a length equal to the number of UIs;
applying a machine learning system to the short pattern waveforms to obtain a value for the one or more measurements; and
providing the values of the one or more measurements for the waveform from the machine learning system.

2. The method as claimed in claim 1, wherein applying the machine learning system to the short pattern waveforms comprises applying the machine learning system to tensors as the short pattern waveforms.

3. The method as claimed in claim 1, wherein applying the machine learning system comprises using one or more short pattern databases to analyze the short pattern waveform.

4. The method as claimed in claim 3, wherein using one or more short pattern databases comprises using only a subset of the one or more short pattern databases.

5. The method as claimed in claim 3, wherein using one or more short pattern databases further comprises removing short pattern databases from the machine learning system that have coefficient values below a threshold to reduce input data size.

6. The method as claimed in claim 1, wherein selecting the number of UIs comprises selecting the number of UIs based upon a number of taps of the equalizer.

7. The method as claimed in claim 1, wherein selecting the number of UIs comprises selecting the number of UIs based on the one or more measurements to be made on the waveform.

8. The method as claimed in claim 1, further comprising training the machine learning system, the training comprising:
setting a length of a short pattern to be used;
selecting a set of short training patterns from a waveform and associated measurements for the set of short training patterns for use by the machine learning system as datasets;
testing the machine learning system to determine if results produced by the machine learning system meet a desired result; and
selecting a different set of the short training patterns and repeating the testing using the different set of short training patterns when the results do not meet the desired result.

9. The method as claimed in claim 8, wherein selecting the different set of the short training patterns comprises selecting a different set of short training patterns of a same length, or selecting a different set of short training patterns having a longer length.

10. The method as claimed in claim 1, wherein the short patterns are stored in a number of short pattern databases, wherein the number, L, of short pattern sequence databases depends upon a number of signal levels, S, used in a type of signaling, and a pattern length, N, according to the relationship L=S^{N}.

11. A test and measurement system, comprising:
a test and measurement device configured to receive a signal from a device under test; and
one or more processors configured to execute code that causes the one or more processors to:
generate a waveform from the signal;
apply an equalizer to the waveform;
receive an input identifying one or more measurements to be made on the waveform;
select a number of unit intervals (UIs) for a known data pattern;
scan the waveform for the known data patterns having a length of the number of UIs;
identify the known data patterns as short pattern waveforms;
apply a machine learning system to the short pattern waveforms to obtain a value for the one or more measurements; and
provide the values of the one or more measurements for the waveform from the machine learning system.

12. The test and measurement system as claimed in claim 11, wherein the short pattern waveforms comprise tensors.

13. The test and measurement system as claimed in claim 11, wherein the code that causes the one or more processors to apply the machine learning system to the short pattern waveforms comprises code that causes the one or more processors to use one or more short pattern waveform databases.

14. The test and measurement system as claimed in claim 13, wherein the code that causes the one or more processors to use one or more short pattern waveform databases comprises code that causes the one or more processors to remove short pattern waveform databases from the machine learning system that have coefficient values below a threshold to reduce input data size.

15. The test and measurement system as claimed in claim 13, wherein the code that causes the one or more processors to use one or more short pattern waveform databases comprises code that causes the one or more processors to use only a subset of the one or more short pattern waveform databases.

16. The test and measurement system as claimed in claim 11, wherein the code that causes the one or more processors to select a number of UIs comprises code to select a number of UIs based upon a number of taps of the equalizer to be applied to the waveform.

17. The test and measurement system as claimed in claim 11, wherein the code that causes the one or more processors to scan the waveform to identify the known data patterns as short pattern waveforms comprises code to select short pattern waveforms and include time sequence information.

18. The test and measurement system as claimed in claim 11, wherein the one or more processors are further configured to execute code to train the machine learning system, that causes the one or more processors to:
set a length of a short training pattern to be used and a subset of the short training patterns with the set short pattern length;
select a subset of available short training patterns from a waveform and associated measurements for the short training patterns to be provided a machine learning system as datasets;
test the machine learning system to determine if results produced by the machine learning system meet a desired result; and
select a different subset of the short training patterns, and repeat the testing when the results do not meet a desired result.

19. The test and measurement system as claimed in claim 18, wherein the code that causes the one or more processors to select a different subset of the short training patterns comprises code that causes the one or more processors to select a different subset of the short training patterns with a same length, or to select a different subset of the short training patterns of a longer length.

20. The test and measurement system as claimed in claim 11, wherein the short patterns are stored in a number of short pattern databases, wherein the number, L, of short pattern sequence databases depends upon a number of signal levels, S, used in a type of signaling, and a pattern length, N, according to the relationship L=S^{N}.
